(19) United States
(12) Patent Application Publication
(10) Pub. No.: US 2026/0372066 A1
(43) Pub. Date: Nov. 19, 2026

(54) METHODS FOR SUBSTRATE PROCESSING WITH SELECTIVE ETCH STOP LAYER

(71) Applicant: Tokyo Electron Limited, Tokyo (JP)

(72) Inventors: Kandabara Tapily, Albany, NY (US); Ayuta Suzuki, Albany, NY (US)

(21) Appl. No.: 19/207,956

(22) Filed: May 14, 2025

(51) Int. Cl. H10W 20/46; H10W 20/00

(52) U.S. Cl. CPC H10W 20/46; H10W 20/072; H10W 20/074; H10W 20/081

(57) ABSTRACT

A method is provided for processing a substrate. The method includes providing a substrate having a metal surface and a dielectric surface. An etch stop layer is selectively deposited over the metal surface while leaving the dielectric surface substantially free of the etch stop layer. The selective deposition includes cyclically exposing the substrate to alternating pulses of a metal-containing precursor and a reactive precursor. A dielectric layer is deposited over the etch stop layer and the dielectric surface. The dielectric layer is etched to create openings that expose portions of the etch stop layer. The exposed portions of the etch stop layer are removed to expose the underlying metal surface.

### TECHNICAL FIELD

The present invention relates generally to a method for semiconductor fabrication, and, in particular embodiments, to a method for semiconductor substrate processing with selective etch stop layer.

### BACKGROUND

Generally, semiconductor devices, such as integrated circuits (ICs), are fabricated by sequentially depositing and patterning layers of dielectric, conductive, and semiconductor materials over a semiconductor substrate. Photolithography and etching processes are employed to form structures that operate as circuit components (e.g., transistors, resistors, and capacitors) and as interconnect elements (e.g., conductive lines, contacts, and vias). The semiconductor industry continuously advances toward higher integration density by reducing minimum feature size, enabling more components to be integrated into a given area. This scaling trend has led to increasingly complex fabrication challenges, particularly in the formation of precisely aligned features at nanometer dimensions.

In semiconductor manufacturing, precise control of etching processes becomes increasingly challenging as feature sizes continue to shrink. During interconnect formation, dielectric materials may be selectively removed to create openings for metal deposition while protecting underlying structures. As dimensions decrease to nanometer scale, the margin for error in these etching processes becomes exceedingly small. Even minor variations in etch depth or profile can lead to significant device performance issues, including increased resistance, poor contact formation, or electrical shorts. This heightened precision requirement drives the need for more effective etch stop strategies that can provide accurate process control while minimizing impact on electrical performance.

### SUMMARY

In accordance with one aspect of the present disclosure, a method is provided for processing a substrate. The method includes providing a substrate comprising a metal surface and a dielectric surface. An etch stop layer is selectively deposited over the metal surface, wherein the selective deposition comprises cyclically exposing the substrate to a pulse of a metal-containing precursor and a pulse of a reactive precursor. A dielectric layer is deposited over the etch stop layer and the dielectric surface. The dielectric layer is etched to expose a top surface of the etch stop layer. The etch stop layer is removed to expose the metal surface.

In accordance with another aspect of the present disclosure, a method is provided for processing a substrate. The method includes providing a substrate comprising a first metal region comprising a metal surface and a first dielectric region comprising a dielectric surface. An etch stop layer is selectively deposited over the metal surface. The first dielectric region is etched, the etching exposing sidewalls of the first metal region. A dielectric layer is deposited to fill openings between the sidewalls, the dielectric layer comprising an air gap.

In accordance with yet another aspect of the present disclosure, a method is provided for processing a substrate. The method includes providing a substrate, the substrate comprising a first etch stop layer deposited over a first metal region. A dielectric layer is deposited over the first etch stop layer and openings in the first metal region. The dielectric layer is etched to expose a top surface of the first etch stop layer. The first etch stop layer is removed and a second metal region is formed over the first metal region. A second etch stop layer is selectively deposited over the second metal region. The dielectric layer is removed to expose sidewalls of the first and second metal regions. A dielectric region is formed in openings between the sidewalls.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1J illustrate cross-sectional views of a method for substrate processing with selective etch stop layer deposition, in accordance with an embodiment;

FIGS. 2A-2F illustrate cross-sectional views of a method for substrate processing with selective etch stop layer deposition and air gap formation, in accordance with an embodiment;

FIGS. 3A-3G illustrate cross-sectional views of a method for substrate processing with air gap structure across multiple metallization levels, in accordance with an embodiment;

FIG. 4 illustrates a gas flow time diagram for a cyclic deposition process used in selective etch stop layer formation, in accordance with an embodiment;

FIGS. 5A-5G illustrate X-ray photoelectron spectroscopy (XPS) characterization data demonstrating the selective deposition mechanism of the etch stop layer, in accordance with an embodiment;

FIG. 6 illustrates comparative X-ray photoelectron spectroscopy (XPS) data for different precursors in the selective deposition process, in accordance with an embodiment;

FIG. 7 illustrates a process flow diagram for substrate processing with selective etch stop layer deposition method, in accordance with an embodiment; and

FIG. 8 illustrates another process flow diagram for substrate processing with selective etch stop layer deposition method, in accordance with an embodiment.

### DETAILED DESCRIPTION OF ILLUSTRATIVE EMBODIMENTS

As semiconductor devices continue to scale down in size, interconnect resistance has emerged as a major bottleneck that negatively impacts power, performance, area, and cost (PPAC) improvements achieved at front-end-of-line (FEOL) steps. The reduction of parasitic effects in interconnect structures has become a priority for the semiconductor industry to maintain the performance trajectory of advanced integrated circuits.

When device feature sizes shrink to nanometer scales, reducing resistance-capacitance (RC) delay presents a challenge, particularly for tight metal pitch configurations in conventional dual damascene processes. In traditional interconnect structures, an etch stop layer (ESL) is deposited uniformly across both metal and dielectric surfaces. The ESL may have a higher dielectric constant (k value) than the surrounding low-k dielectric material, resulting in increased parasitic capacitance that contributes negatively to overall RC delay.

In various embodiments of the present disclosure, selective deposition of etch stop layers is exclusively applied on metal surfaces while leaving dielectric surfaces free of ESL material. In some embodiments, this selective ESL approach may utilize a chemical reaction between a metal-containing precursor (such as dimethylaluminum isopropoxide) and a reactive precursor (such as carboxylic acid or alcohol) to form a metal oxycarbide layer that grows selectively on metal surfaces through a self-limiting reaction mechanism. The selective ESL approach may eliminate the high-k ESL material from dielectric regions to reduce the overall effective dielectric constant of the interconnect structure, leading to lower parasitic capacitance and improved RC delay characteristics.

In one or more embodiments, the selective ESL deposition approach may be combined with additional approaches such as air gap formation within dielectric materials or 2D sidewall barrier implementation to further reduce parasitic capacitance. Additionally, the selective ESL deposition approach may be applied across multiple metallization levels, enabling comprehensive parasitic capacitance reduction throughout the interconnect hierarchy.

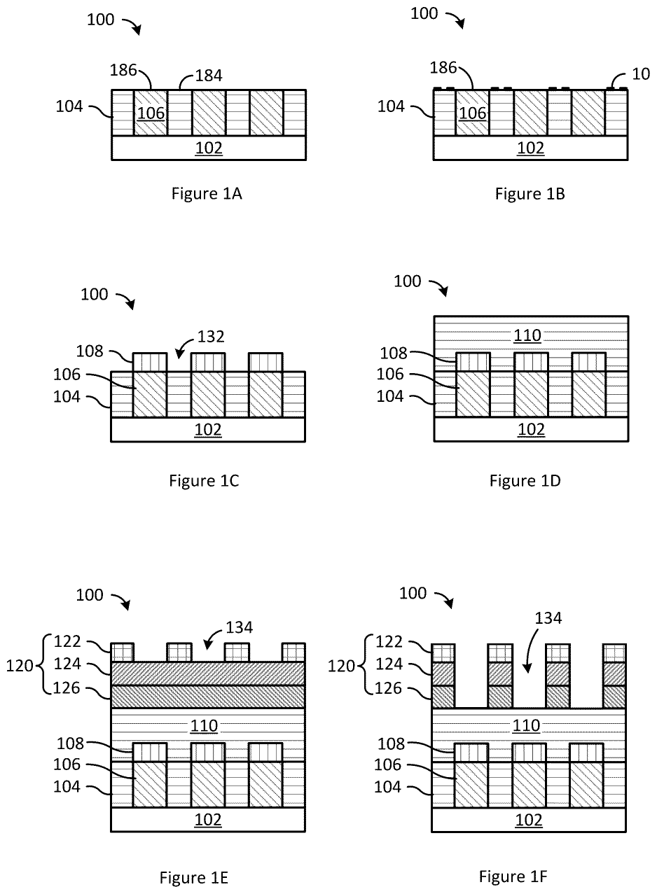

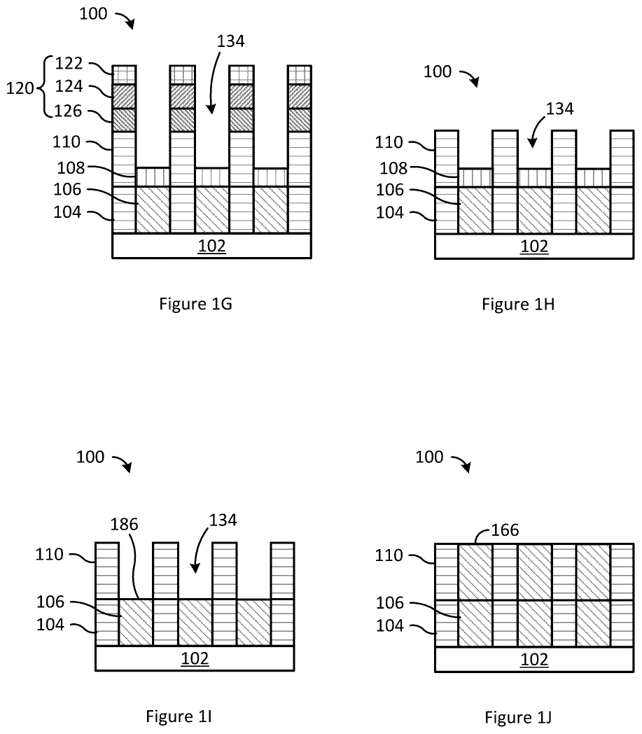

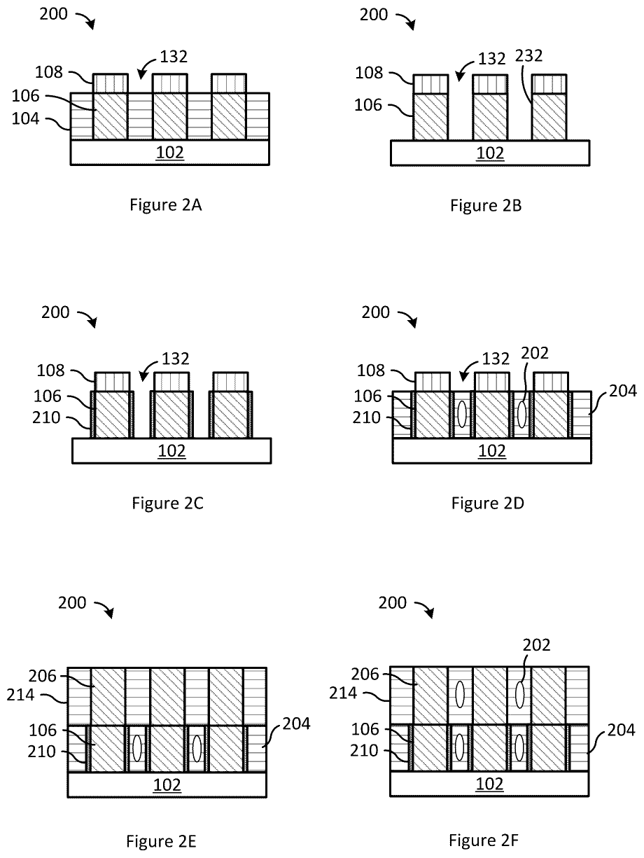

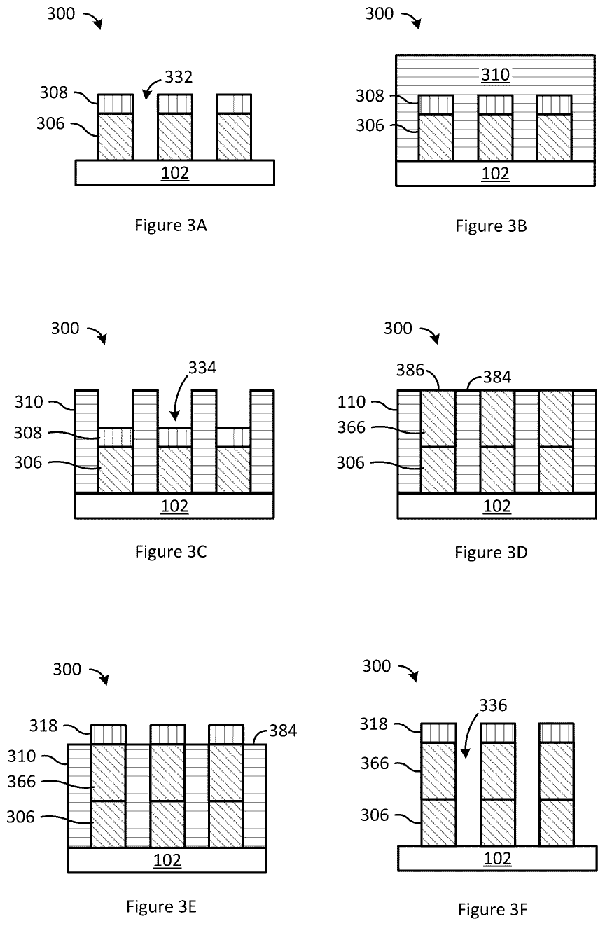

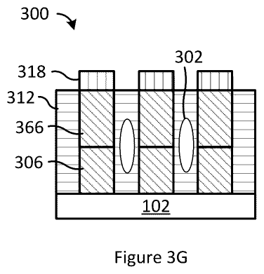

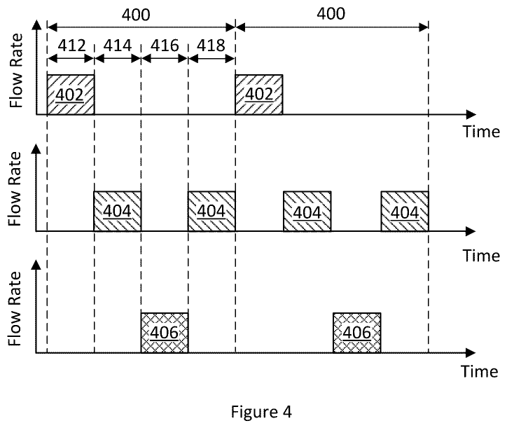

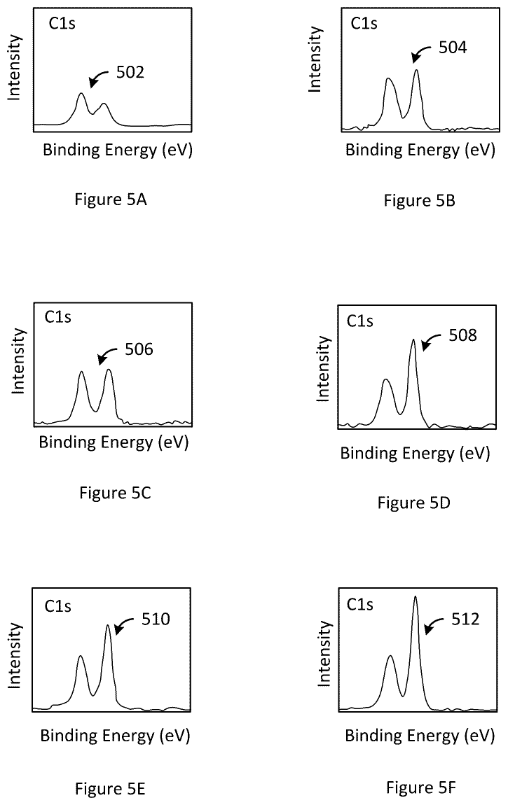

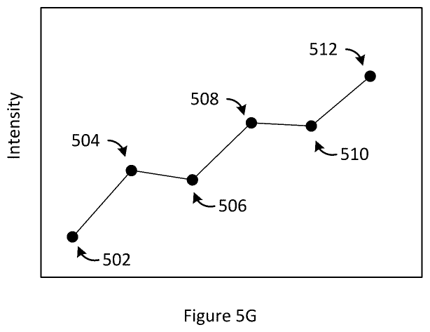

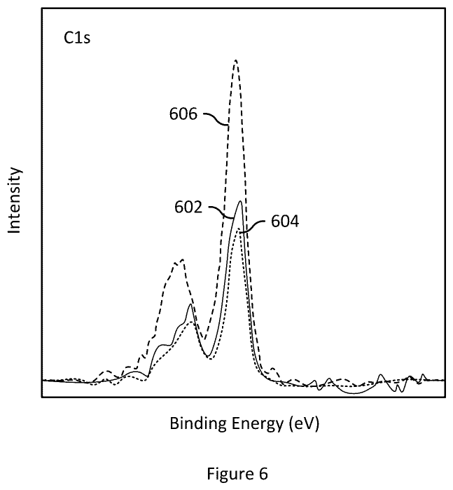

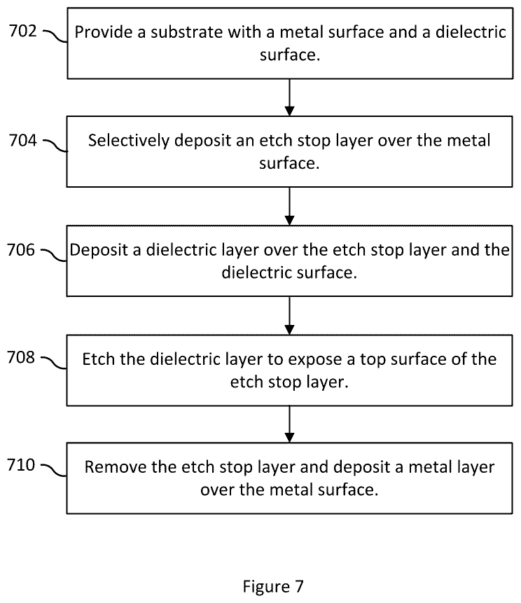

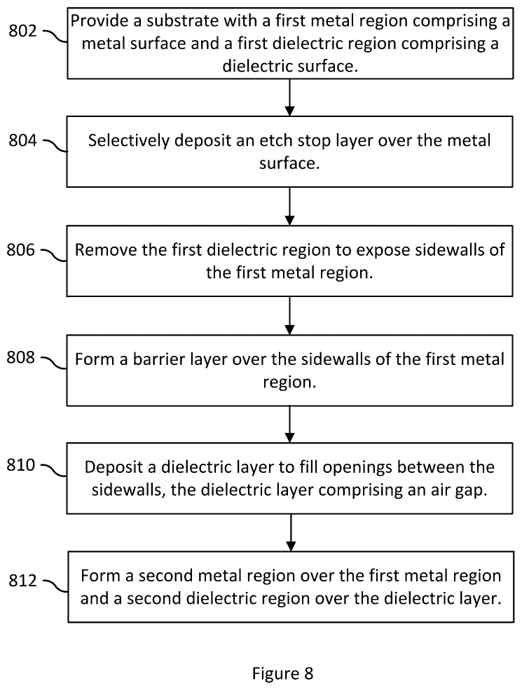

Embodiments of the disclosure are described in the context of the accompanying drawings. An embodiment of a process flow for processing a substrate through selective etch stop layer is illustrated in FIGS. 1A-1J. Another embodiment incorporating air gap formation with barrier layers is illustrated in FIGS. 2A-2F. One more embodiment featuring substrate processing with air gap structure across multiple metallization levels is shown in FIGS. 3A-3G. A cyclic deposition process for the selective etch stop layer is represented in the gas flow time diagram of FIG. 4. Experimental X-ray photoelectron spectroscopy (XPS) characterization data illustrating the selective deposition mechanism is presented in FIGS. 5A-5G, with additional comparative data shown in FIG. 6. Process flow diagrams for the substrate processing with selective etch stop layer deposition are provided in FIGS. 7 and 8.

FIGS. 1A-1J illustrate cross-sectional views of steps of processing a substrate with selective etch stop layer deposition, in accordance with an embodiment.

In FIG. 1A, a substrate 100 may be loaded into a process chamber. The substrate 100 may comprise a substrate layer 102, a first dielectric region 104 and a first metal region 106 disposed over the substrate layer 102.

In various embodiments, the substrate layer 102 may comprise a bulk substrate such as a blank silicon wafer, a silicon-on-insulator (SOI) wafer, or any of various other semiconductor substrates. The substrate layer 102 may also be coated or layered with any number of additional materials, including compound semiconductors, metal or metal oxides, or metal nitrides. The substrate layer 102 may include any material portion or structure of a device, particularly a semiconductor or other electronics device.

In various embodiments, the first metal region 106 may comprise a metal surface 186 and comprise metallic materials such as ruthenium (Ru), molybdenum (Mo), tungsten (W), cobalt (Co), copper (Cu), copper-aluminum alloy (CuAl), nickel-aluminum alloy (NiAl), niobium (Nb), nickel (Ni), or aluminum (Al). In various embodiments, the first dielectric region 104 may comprise a dielectric surface 184 and comprise materials such as silicon oxide (SiO), silicon oxycarbide (SiOC), silicon oxycarbonitride (SiOCN), or silicon carbonitride (SiCN). The first dielectric region 104 may isolate different first metal regions 106 from electrical contacts.

In one or more embodiments, a structure of the first metal and first dielectric regions 106 and 104 may represent an interconnect structure where metal lines are embedded in a dielectric material. The metal lines may serve as a capping layer for an underlying copper interconnect or as a standalone interconnect line.

FIG. 1B illustrates a cross-sectional view of a surface treatment process applied to the substrate 100, in accordance with one embodiment. A surface treatment material 10 may be selectively applied to the dielectric surface 184 of the first dielectric region 104 before subsequent etch stop layer deposition. This treatment may serve to further inhibit etch stop layer growth over the dielectric surface 184 during subsequent processing steps.

In various embodiments, the surface treatment material 10 may comprise phosphonic, carboxyllic, amine, carbene, silane inhibitor molecules such as trimethylsilyldimethylamine (TMSDMA), which may selectively adhere to the dielectric surface 184. In one or more embodiments, the surface treatment material 10 may also comprise other silanes such as hexamethyldisilazane (HMDS), bis(dimethylamino)dimethylsilane (DMADMS), trimethylchlorosilane (TMCS), octadecyltrichlorosilane (OTS), dimethyldichlorosilane (DMDCS), or the like. These silane-based materials may form self-assembled monolayers on the dielectric surface 184, creating a chemical barrier that inhibits subsequent etch stop layer deposition.

In various embodiments, the surface treatment material 10 may be applied using various techniques including vapor phase deposition, liquid phase deposition, or plasma-enhanced deposition. In an embodiment, the surface treatment process may be performed at temperatures ranging from room temperature to approximately 400° C, with process time ranging from a few seconds to several minutes depending on the specific silane compound.

In various embodiments, selective adhesion of the surface treatment material 10 to the dielectric surface 184 may occur due to the chemical affinity between the silane compounds and the surface materials. For example, when the dielectric surface 184 comprises silicon dioxide or other oxide materials, the silane compounds react with hydroxyl groups on the oxide surface to form covalent bonds, creating a well-adhered monolayer.

In FIG. 1C, a selective etch stop layer deposition process may be applied to the substrate 100, in accordance with one embodiment. An etch stop layer 108 may be selectively disposed over the metal surface 186 of the first metal region 106, while leaving the dielectric surface 184 free of the etch stop layer deposition. A first opening 132 may remain within the area above the dielectric surface 184 where no etch stop layer is deposited.

In various embodiments, the etch stop layer 108 may comprise silicon carbonitride (SiCN), silicon nitride (SiN), silicon oxycarbonitride (SiOCN), aluminum oxynitride (AlON), aluminum oxycarbide (AlOC), aluminum nitride (AlN), or aluminum carbonitride (AlCN). In some embodiments, the etch stop layer 108 may comprise other metal oxides, such as hafnium oxide (HfO₂), zirconium oxide (ZrO₂), titanium oxide (TiO₂), tantalum oxide (Ta₂O₅), yttrium oxide (Y₂O₃), lanthanum oxide (La₂O₃), aluminum oxide (Al₂O₃), or combinations thereof.

In various embodiments, the etch stop layer 108 may be selectively deposited over the metal surface 186 by cyclically exposing the substrate 100 to a pulse of a metal-containing precursor and a pulse of a reactive precursor. The metal-containing precursor may comprise compounds containing at least one of aluminum, silicon, hafnium, zirconium, titanium, tantalum, yttrium, lanthanum, or combinations thereof. In some embodiments, the metal-containing precursors may include organometallic compounds such as dimethylaluminum isopropoxide (DMAI), trimethylaluminum (TMA), tetrakis(dimethylamino)hafnium (TDMAH), tetrakis(ethylmethylamino)zirconium (TEMAZ), titanium tetrachloride (TiCl₄), tantalum pentachloride (TaCl₅), or silicon-containing compounds such as bis(tertiary-butylamino)silane (BTBAS) or tris(dimethylamino)silane (3DMAS). The reactive precursor may comprise compounds that provide oxygen, nitrogen, carbon, or combinations thereof to form the desired etch stop layer composition. In one or more embodiments, the reactive precursor may be a reactive organic precursor comprising organic compounds. In various embodiments, the reactive precursors may include oxygen-containing organic compounds such as carboxylic acids (e.g., succinic acid), alcohols (e.g., hydroquinone), or inorganic materials such as water, ozone, or oxygen plasma; nitrogen-containing compounds such as ammonia, hydrazine, nitrogen plasma, or amines; and carbon-containing compounds such as methane, ethylene, acetylene, or carbon-containing plasma. The specific combination of metal-containing precursor and reactive precursor may be selected based on the desired composition of the etch stop layer 108. For example, aluminum oxycarbide (AlOC) may be formed using DMAI and succinic acid, while hafnium oxide (HfO₂) may be formed using TDMAH and water or ozone or succinic acid or combination of thereof. In one or more embodiments, the cyclic exposure process may be performed at temperatures below 100° C. to maintain selectivity, with each cycle including appropriate purge steps using inert gases to remove excess precursors and reaction byproducts.

In various embodiments, deposition of the etch stop layer 108 may be implemented with any suitable technique, such as atomic layer deposition (ALD), pulsed laser deposition (PLD), chemical vapor deposition (CVD), plasma-enhanced CVD or ALD, or any other layer deposition process or combination thereof. In one or more embodiments, the etch stop layer 108 may comprise a thickness smaller than 5 nm, which may be sufficient to provide the necessary etch protection while minimize parasitic capacitance.

In some embodiments, the etch stop layer 108 may be deposited using the ALD method. In one embodiment, the substrate 100 may be cyclically exposed to alternating pulses of an aluminum-containing precursor and an organic compound. In one or more embodiments, the aluminum-containing precursor may be dimethylaluminum isopropoxide (DMAI) or trimethylaluminum (TMA), while the organic compound may be a carboxylic acid such as succinic acid (SA) or an alcohol compound such as hydroquinone (HQ). In some embodiments, a combination of both succinic acid and hydroquinone may be used. A purge step using an inert gas such as argon or nitrogen may be used between the alternating pulses to remove excess precursor and reaction byproducts.

In various embodiments, the cyclic process of depositing the etch stop layer 108 may be performed at a temperature below 150° C., for example, 85° C. At temperature below 150° C., the precursors may react preferentially with the metal surface 186 while showing minimal reactivity with the dielectric surface 184 or the surface treatment material 10. In some embodiments, the surface treatment material 10 may serve as passivation agents for the dielectric surface to inhibit etch stop layer growth.

FIG. 1D illustrates a cross-sectional view of a dielectric layer deposition process. In various embodiments, a dielectric layer 110 may be disposed over both the etch stop layer 108 and the first dielectric region 104. In various embodiments, the dielectric layer 110 may be deposited using various techniques including atomic layer deposition (ALD), chemical vapor deposition (CVD), or physical vapor deposition (PVD). In one or more embodiments, the dielectric layer 110 may comprise similar dielectric materials of the first dielectric region 104, such as silicon oxide (SiO), silicon oxycarbide (SiOC), silicon oxycarbonitride (SiOCN), or silicon carbonitride (SiCN).

In some embodiments, the surface treatment material 10 may be removed before depositing the dielectric layer 110. This removal step may be accomplished through techniques such as plasma treatment, thermal annealing, or chemical cleaning. In some embodiments, the removal of the surface treatment material 10 may enhance adhesion between the dielectric layer 110 and the first dielectric region 104, improving the mechanical stability.

In FIG. 1E, a patterning process may be applied to the dielectric layer 110, in accordance with one embodiment. A patterning stack 120 may be deposited over the dielectric layer 110 to facilitate the formation of precise openings in the dielectric material. In various embodiments, the patterning stack 120 may comprise multiple layers including a bottom anti-reflective coating (BARC) layer 124 and a hard mask layer 126, with a patterned photoresist layer 122 on top forming second openings 134.

In various embodiments, the BARC layer 124 may serve to minimize reflection during lithography, which helps prevent standing waves and improves pattern fidelity. The BARC layer 124 may comprise organic materials such as polyimides, polycarbonates, polyarylethers, or inorganic materials such as silicon oxynitride, silicon nitride, or titanium nitride.

The hard mask layer 126 may provide pattern transfer capability with enhanced etch selectivity compared to photoresist. In one or more embodiments, the hard mask layer 126 may comprise materials such as silicon oxide, silicon nitride, silicon oxynitride, silicon carbide, titanium nitride, tantalum nitride, or amorphous carbon. The hard mask layer 126 may enable the transfer of smaller features and higher aspect ratio structures that might be challenging to achieve with photoresist alone.

In various embodiments, the patterned photoresist layer 122 may be formed through a lithography process, which may include applying a photoresist material, exposing selected areas to light through a mask, and developing the exposed areas to create the pattern. The photoresist may be a positive or negative resist and may be composed of various photosensitive polymers including phenol formaldehyde resins, polyhydroxystyrene derivatives, or chemically amplified resists. In one or more embodiments, the lithography process for forming the pattern may utilize various techniques including deep ultraviolet (DUV) lithography, extreme ultraviolet (EUV) lithography, electron beam lithography, or nanoimprint lithography, depending on the resolution requirements of the specific technology node. The second openings 134 in the patterning stack 120 may define the locations where trenches or vias may be formed in the underlying dielectric layer 110, eventually connecting to the first metal region 106 below.

In some embodiments, the patterning stack 120 may also comprise additional layers not shown, such as adhesion promotion layers, planarization layers, or multiple hard mask layers, depending on the complexity of the pattern and the specific requirements of the fabrication process.

In FIGS. 1F-1G, an etching process may be performed to transfer the pattern from the patterned photoresist layer 122 through the patterning stack 120 and into the dielectric layer 110, in accordance with one embodiment. This pattern transfer process may create second openings 134 that extend through the dielectric layer 110 down to the etch stop layer 108. The dielectric layer 110 after the etching process may also be referred to as a second dielectric region 110.

In FIG. 1F, the pattern of the patterned photoresist layer 122 may be first transferred to the BARC layer 124, then the hard mask layer 126 through the etching processes. In various embodiments, the etching processes may comprise oxygen-based plasma etch for BARC, fluorocarbon-based plasmas (such as CF₄, C₄F₈, or CHF₃) for silicon-based hard masks, or chlorine-based plasmas for metal-based hard masks.

In FIG. 1G, the pattern of the patterning stack 120 may be transferred into the dielectric layer 110 using an etch chemistry appropriate for the specific dielectric material. For silicon oxide-based dielectrics, fluorocarbon-based plasma may be used to etch the dielectric layer 110. The etching process may stop at the etch stop layer 108, which protects the underlying metal region 106 from being damaged during the dielectric etch. The substrate 100 after the etching process may have the second openings 134 in the dielectric layer 110 that are aligned with the first metal region 106 below, with a surface of the etch stop layer 108 exposed at the bottom of the second openings 134.

In FIG. 1H, the patterning stack 120 may be removed from the substrate 100, in accordance with one embodiment. Following the pattern transfer and etching of the dielectric layer 110 to form the second openings 134, the remaining portions of the patterning stack 120 (including the patterned photoresist layer 122, BARC layer 124, and hard mask layer 126) may be removed to prepare the structure for subsequent processing steps.

In FIG. 1I, the etch stop layer 108 at the bottom of the second openings 134 may be removed. The removal process may expose the metal surface 186 of the first metal region 106, creating a direct pathway for electrical connection with subsequent metallization.

The removal of the etch stop layer 108 may be accomplished through various methods depending on its composition. In embodiments where the etch stop layer 108 comprising aluminum-based materials (such as AlOC, AlON, AlN, AlCN), wet chemical etching using heated phosphoric acid solutions, reactive ion etching with chlorine-based plasmas, or fluorine-based plasma treatments with oxygen mixtures may be applied. In embodiments where the etch stop layer 108 comprising silicon-based materials (such as SiCN, SiN, SiOCN), removal techniques including hot phosphoric acid wet etching, fluorocarbon plasma-based dry etching, or hydrogen-based plasma treatments may be applied.

In FIG. 1J, a metal layer 166 may be deposited over the substrate 100, in accordance with one embodiment. The metal layer 166, which may also be referred to as a second metal region 166, may fill the second openings 134 between portions of the dielectric layer 110 and establish direct contact with the metal surface 186 of the first metal region 106. This metal-to-metal contact (between the first and second metal regions 106 and 166) creates electrical pathways between different levels of the interconnect structure.

In various embodiments, the second metal region 166 may comprise materials similar to those used for the first metal region 106, including ruthenium (Ru), molybdenum (Mo), tungsten (W), cobalt (Co), copper (Cu), copper-aluminum alloy (CuAl), nickel-aluminum alloy (NiAl), niobium (Nb), nickel (Ni), or aluminum (Al). The metal deposition process may involve techniques such as physical vapor deposition (PVD), chemical vapor deposition (CVD), atomic layer deposition (ALD), electroplating, or electroless plating, depending on the specific metal material and the dimensional requirements of the interconnect structure. For copper metallization, the process may include a thin barrier/liner layer deposition followed by a copper seed layer and subsequent copper fill through electroplating or electroless plating.

By depositing the etch stop layer 108 exclusively on the metal surfaces, the substrate may eliminate the high-k etch stop component from dielectric regions. Since conventional etch stop materials may have higher dielectric constants than the surrounding low-k dielectric, the selective etch stop layer deposition may reduce parasitic capacitance between adjacent metal regions. The reduction in parasitic capacitance may directly translate to improved RC delay characteristics with feature sizes scaling down. In various embodiments, the process sequence illustrated in FIGS. 1A-1J may be repeated multiple times to form complex multi-level interconnect structures, with each level benefiting from the selective etch stop layer deposition approach. This scalable methodology may enable the creation of high-performance interconnect hierarchies with optimized signal propagation characteristics throughout the entire device.

FIGS. 2A-2F illustrate another method of processing the substrate with selective etch stop layer deposition, in accordance with an embodiment. The method in FIGS. 2A-2F differs from the method in FIGS. 1A-1J in an air gap formation to further reduce the parasitic capacitance. Components and features in FIGS. 2A-2F that share reference numbers with those in FIGS. 1A-1J have corresponding, structures, materials and deposition methods as previously described.

In FIG. 2A, a substrate 200 is provided. The substrate 200 may be similar to the substrate 100 illustrated in FIG. 1C. The substrate 200 may comprise the substrate layer 102 and the first dielectric and first metal regions 104 and 106 disposed over the substrate layer 102. The etch stop layer 108 may be selectively deposited over the first metal region 106 as described previously. The first openings 132 may be formed between portions of the etch stop layer 108.

In FIG. 2B, an etching process may be performed on the substrate 200 to remove the first dielectric region 104. In various embodiments, the etching process may expose sidewalls 232 of the first metal region 106. The etch stop layer 108 may protect the top surface of the first metal region 106 during this etching process, preventing damage to the metal surface. In various embodiments, the etching process may comprise wet etching using solutions such as dilute hydrofluoric acid for silicon oxide-based dielectrics or specialized solvents for organic low-k materials. In alternative embodiments, the etching process may comprise dry etching techniques such as reactive ion etching (RIE), inductively coupled plasma (ICP) etching, or downstream plasma etching may be employed with gas chemistries tailored to the specific dielectric material. In some embodiments, more precise approaches such as atomic layer etching (ALE) or cyclic etch-deposition processes may be used to achieve highly controlled removal of the dielectric with minimal impact on the metal surfaces.

In FIG. 2C, a barrier layer 210 may be formed over the sidewalls 232 of the first metal region 106. In one or more embodiments, the barrier layer 210 may serve to prevent diffusion of metal atoms from the first metal region 106 into surrounding dielectric materials and provides enhanced adhesion for subsequent layers. The barrier layer 210 may comprise a thickness ranging from 1 to 7 nm, for example, approximately 5 nm, which may provide effective barrier properties while minimize the impact on the available space for subsequent dielectric fill.

In various embodiments, the barrier layer 210 may comprise transition metal dichalcogenides (TMDCs) such as molybdenum disulfide (MoS₂) or tungsten diselenide (WSe₂), graphene, nitrides such as titanium nitride (TiN) or tantalum nitride (TaN), or oxides such as aluminum oxide (Al₂O₃) or tantalum oxide (Ta₂O₅). The barrier layer 210 may be deposited using techniques such as atomic layer deposition (ALD), chemical vapor deposition (CVD), physical vapor deposition (PVD), or specialized deposition methods for 2D materials such as chemical vapor transport (CVT), metal-organic chemical vapor deposition (MOCVD), molecular beam epitaxy (MBE), pulsed laser deposition (PLD), or sulfurization/selenization of pre-deposited metal films.

In FIG. 2D, a dielectric layer 204 may be deposited to fill openings between the barrier layers 210 that cover the sidewalls of the first metal region 106. In various embodiments, the dielectric layer 204 may comprise an air gap 202, also referred to as a void, which provides a region with a low dielectric constant between 1.0 and 1.1. The low dielectric constant of air gap 202 may further reduce parasitic capacitance between metal regions to improve RC delay.

In one or more embodiments, the air gap 202 may be formed using an ashless carbon approach, where an ashless carbon material may be first deposited within the openings between the sidewalls 232. In various embodiments, the ashless carbon material may comprise amorphous carbon, hydrogenated amorphous carbon, fluorinated amorphous carbon, or specialized polymeric carbon precursors designed to decompose cleanly without residue. Following the carbon deposition, a dielectric material may be deposited over the ashless carbon to seal the openings. The substrate 200 may be then subjected to an annealing process at elevated temperatures between 300° C. and 600° C., which may cause the ashless carbon to decompose into volatile components that diffuse through the dielectric capping layer, leaving behind a clean void that forms the air gap 202.

In alternative embodiments, the air gap 202 may be formed using a nonconformal chemical vapor deposition (CVD) process. In this approach, a dielectric material may be deposited using conditions that promote faster deposition at the top portions of the openings (between the sidewalls 232) compared to the bottom portions. As the deposition progresses, the material accumulates more thickly at the upper regions, eventually closing off the top of the opening before the entire space is filled. The nonconformal CVD may create a void within the structure that serves as the air gap.

Even though FIG. 2D only illustrates one air gap 202, the dielectric layer 204 may comprise a plurality of air gaps (e.g., millions to billions of air gaps) rather than a single continuous void, depending on the specific process conditions and geometry of the openings. Multiple smaller air gaps may form naturally during the ashless carbon removal process due to local variations in decomposition and diffusion rates. Similarly, in the nonconformal CVD approach, the closure pattern may create segmented voids rather than a continuous channel. These distributed air gaps may provide the benefit of low dielectric constant while offer improved mechanical stability compared to larger continuous voids.

In FIG. 2E, additional metallization levels may be formed. Following the processing steps similar to those illustrated in FIGS. 1D through 1J, a second dielectric region 214 may be formed over the dielectric layer 204, and a second metal region 206 may be formed over the first metal region 106, establishing electrical connections between the metallization levels. In various embodiments, the second dielectric region 214 may serve as the insulating material between metal features at this level of the interconnect structure. This sequential build-up of metallization and dielectric layers enables the creation of complex multi-level interconnect structures necessary for advanced semiconductor devices.

In FIG. 2F, a variation of the substrate 200 in FIG. 2E is illustrated where the second dielectric region 214 may comprise the air gap 202 as described previously for FIG. 2D. The air gap in the second dielectric region 214 may be formed using the same techniques described previously, either through the ashless carbon method or the nonconformal CVD approach. By incorporating air gaps at multiple metal levels, the substrate may achieve parasitic capacitance reduction throughout the interconnect stack, leading to improved RC delay characteristics. This multi-level air gap implementation demonstrates the scalability of the approach for creating high-performance interconnect structures with optimized electrical properties across all metallization levels.

FIGS. 3A-3G illustrate yet another method of processing the substrate with selective etch stop layer deposition, in accordance with an embodiment. The method in FIGS. 3A-3G differs from previous embodiment methods in formation of air gap throughout multiple dielectric and metal region stacks. Components and features in FIGS. 3A-3G that share reference numbers with those in FIGS. 1A-1J have corresponding, structures, materials and deposition methods as previously described.

In FIG. 3A, a substrate 300 similar to the substrate 200 illustrated in FIG. 2B is provided. In various embodiments, the substrate 300 may comprise the substrate layer 102 and a first metal region 306 disposed over the substrate layer 102. The first metal region 306 may comprise similar structures and materials of the first metal region 106 described previously. In one or more embodiments, a first etch stop layer 308 similar to the etch stop layer 108 may be selectively deposited over the first metal region 306. The first metal region 306 may comprise openings 332 between different portions. In one or more embodiments, a barrier layer similar to the barrier layer 210 may be formed over sidewalls of the first metal region 306.

In FIG. 3B, a dielectric layer 310 may be deposited over the first etch stop layer 308 and openings 332 in the first metal region 306. The dielectric layer 310 may comprise similar materials and deposition methods to the dielectric layer 110 as described with reference to FIG. 1D.

In FIG. 3C, the dielectric layer 310 may be etched to expose a top surface of the first etch stop layer 308. The etching process may follow steps similar to those illustrated in FIGS. 1D through 1H. In various embodiments, a patterning stack similar to the patterning stack 120 may be first deposited over the dielectric layer 310, followed by lithographic patterning to define openings. The pattern may be then transferred through the dielectric layer 310 using appropriate etching techniques until the first etch stop layer 308 is exposed at the bottom of the openings. Subsequently, the patterning stack is removed, and the exposed portions of the first etch stop layer 308 may be selectively etched away to reveal the top surface of the first metal region 306. This sequence of processing steps may create precisely positioned openings 334 in the dielectric layer 310 that provide access to the underlying metal regions 306, enabling the formation of electrical connections between different metallization levels while maintaining the benefits of the selective etch stop layer approach.

In FIG. 3D, a second metal region 366 may be deposited over the first metal region 306 after the removal of the first etch stop layer 308. This metal deposition process is similar to that illustrated in FIG. 1J with the second metal region 366 filling the openings 334 in the dielectric layer 310. In various embodiments, the resulting surface of the substrate 300 may comprise exposed metal surfaces 386 of the second metal region 366 and exposed dielectric surfaces 384 of the dielectric layer 310. The second metal region 366 may comprise materials similar to the first metal region 306, including various metals and metal alloys suitable for semiconductor interconnects.

In FIG. 3E, a second etch stop layer 318 may be selectively deposited over the exposed metal surfaces 386 of the second metal region 366. This selective deposition process is similar to that described in FIGS. 1A-1C of the first embodiment. In some embodiments, prior to the selective deposition, an optional surface treatment as described in FIG. 1B may be applied to the exposed dielectric surfaces 384 to further enhance selectivity by inhibiting deposition on these areas. In various embodiments, the second etch stop layer 318 may comprise materials similar to those used for the first etch stop layer 308, including metal oxide, metal oxycarbide, metal oxynitride, metal nitride, or metal carbonitride. In various embodiments, the deposition of the second etch stop layer 318 may comprise similar methods to deposit the etch stop layer 108.

In FIG. 3F, the dielectric layer 310 may be removed using an etching process similar to that described with reference to FIG. 2B. The etching process may form openings 336 that expose sidewalls of both the first and the second metal regions 306 and 366. The etching may be accomplished through various methods including wet etching, reactive ion etching (RIE), inductively coupled plasma etching, or other techniques appropriate for the specific dielectric material. In some embodiments, a barrier layer similar to the barrier layer 210 may be formed over the sidewalls after the etching process.

In FIG. 3G, a dielectric region 312 may be formed to fill the openings 336 between the sidewalls of the first metal region 306 and the second metal region 366. The dielectric region 312 may comprise similar materials and deposition methods of the first dielectric region 104 as described with reference to FIG. 1A. In various embodiments, the dielectric region 312 may comprise an air gap 302 similar to the air gap 202 with a dielectric constant between 1.0 and 1.1. The air gap 302 may be formed using processes similar to those described for forming the air gap 202 in FIG. 2D, such as the ashless carbon method or the nonconformal CVD approach. In various embodiments, the air gap 302 may be a continuous void spanning across multiple metallization levels, creating a unified low-k region that minimizes parasitic capacitance throughout the interconnect structure. In alternative embodiments, the air gap 302 may manifest as multiple discrete air gaps distributed throughout the structure, which can provide enhanced mechanical stability while still delivering substantial capacitance reduction benefits. This multi-level air gap implementation combines the selective etch stop layer technique with air gap integration to achieve improved RC delay characteristics in complex semiconductor devices.

Throughout the process flows illustrated in FIGS. 1A-1J, 2A-2F, 3A-3G, various additional steps may be performed that are not explicitly shown in the figures. These may include in-situ or ex-situ cleaning steps to remove residues or contaminants between processing operations, such as post-etch cleaning, or pre-deposition surface preparation. Chamber transfer operations between different process tools may occur, potentially with vacuum breaks requiring specialized handling procedures to prevent oxidation or contamination. Metrology and inspection steps may be conducted at various stages to verify critical dimensions, film thicknesses, or detect defects. Additionally, annealing or curing processes may be performed to stabilize materials, reduce stress, or improve electrical characteristics. It is important to note that while the illustrated embodiments show the formation of one or two metal levels, the processes described can be repeated multiple times to build interconnect structures with many more metallization levels, each potentially incorporating the selective etch stop layer approach and/or air gap formation techniques to optimize performance throughout the entire interconnect hierarchy.

FIG. 4 illustrates a gas flow time diagram for the cyclic deposition process used to form the etch stop layers 108, 308, or 318, in accordance with an embodiment. The diagram shows the timing and sequence of precursor and purge gas pulses that constitute one complete deposition cycle, which may be repeated multiple times to achieve the desired etch stop layer thickness.

In various embodiments, a cycle period 400 may begin with a pulse of metal-containing precursor 402 (such as dimethylaluminum isopropoxide or trimethylaluminum) introduced into the process chamber for a first time duration 412. This may be followed by a pulse of inert gas 404 (such as argon or nitrogen) for a second time duration 414, which serves to purge excess precursor and reaction byproducts from the chamber. Next, a pulse of reactive precursor 406 (such as carboxylic acid or alcohol compound) may be delivered for a third time duration 416. The cycle period 400 may conclude with another pulse of inert gas 404 for a fourth time duration 418 to complete the purge process.

In various embodiments, the controlled sequence may enable self-limiting surface reactions for achieving selective deposition on metal surfaces while preventing growth on dielectric surfaces. The timing of each pulse and purge step may be optimized to ensure complete surface reactions and effective removal of excess reactants, ranging from a few hundred milliseconds to several seconds depending on the specific precursors and chamber configuration. In various embodiments, the entire cycle may be conducted at temperatures below 100° C. to maintain selectivity and prevent thermal decomposition of the precursors. By repeating the cycle period 400 multiple times, the etch stop layer may grow in a controlled manner exclusively on the metal surfaces, enabling the parasitic capacitance reduction benefits described in the various embodiments.

FIGS. 5A-5G and 6 present X-ray photoelectron spectroscopy (XPS) characterization data demonstrating the selective deposition mechanism of the etch stop layer, using aluminum oxycarbide (AlOC) formation as an example. FIGS. 5A-5G show C1s XPS signals at different stages of the cyclic deposition process.

FIG. 5A shows the C1s intensity curve 502 before the cyclic process begins, establishing the baseline carbon content on the surface. FIG. 5B displays the C1s intensity curve 504 after the first pulse of succinic acid (SA), showing an increase in carbon content due to the adsorption of the carboxylic acid on the surface. FIG. 5C presents the C1s intensity curve 506 after the first pulse of dimethylaluminum isopropoxide (DMAI) showing similar carbon content with the curve 504. Increased C1s intensity after the first SA and DMAI pulses indicates the reaction between the aluminum precursor and the succinic acid to form aluminum oxycarbide.

The process continues in FIG. 5D, showing the C1s intensity curve 508 after the second pulse of succinic acid, and FIG. 5E, displaying the intensity curve 510 after the second pulse of DMAI. FIG. 5F shows the C1s intensity curve 512 after the third pulse of succinic acid. Throughout this sequence, the consistent increase in the C-C peak height with each SA+DMAI cycle demonstrates the progressive growth of the aluminum oxycarbide layer on the surface.

FIG. 5G summarizes the trend by plotting the C-C peak height across all steps of the deposition process, clearly illustrating the stepwise increase in carbon content that correlates with the cyclic application of precursors. This data confirms that the reaction between the aluminum precursor and succinic acid successfully forms the desired aluminum oxycarbide material, and that the growth occurs in a controlled manner with each deposition cycle.

FIG. 6 shows C1s intensity curves between pure SA pulses and alternating pulses of SA and TMA. C1s intensity curve 602 is measured after exposing the substrate surface to one pulse of SA, while C1s intensity curve 604 refers to exposure of repeating pulses of SA. Both intensity curves show limited differences, suggesting that once the surface is covered with a monolayer of the acid, additional exposure does not significantly change the surface composition. However, when alternating pulses of SA and TMA are applied, the C1s intensity curve 606 shows a substantial increase in carbon content. This demonstrates the formation of aluminum oxycarbide material which contributes to C1s intensity increment. The XPS analysis provides evidences for the chemical mechanism underlying the selective deposition process that enables the formation of the etch stop layer exclusively on metal surfaces.

FIG. 7 illustrates a flow diagram of a method for processing a substrate with selective etch stop layer deposition, in accordance with an embodiment.

At block 702, a substrate with a metal surface and a dielectric surface may be provided. This substrate may be similar to the substrate 100 as described with reference to FIG. 1A, comprising the first metal region 106 with the metal surface 186 and the first dielectric region 104 with the dielectric surface 184.

At block 704, an etch stop layer may be selectively deposited over the metal surface. This selective deposition process may follow the methods described with reference to FIG. 1C, where the etch stop layer 108 may be selectively deposited on the metal surface 186 while leaving the dielectric surface 184 substantially free of the etch stop layer. The selective deposition may be achieved through cyclic processes as detailed in the descriptions of FIGS. 1C and 4. In some embodiments, a surface treatment similar to the process described with reference to FIG. 1B may be applied to the substrate before the selective deposition of etch stop layer.

At block 706, a dielectric layer may be deposited over the etch stop layer and the dielectric surface. This dielectric layer may correspond to the dielectric layer 110 described with reference to FIG. 1D, and may comprise various low-k dielectric materials as previously discussed. The deposition may be performed using techniques such as chemical vapor deposition (CVD), plasma-enhanced chemical vapor deposition (PECVD), or spin-on dielectric processes as described previously.

At block 708, the dielectric layer may be etched to expose a top surface of the etch stop layer. This etching process may follow the methods described with reference to FIGS. 1E through 1H, including the formation of the patterning stack 120, lithographic patterning, and subsequent etching to create second openings 134 that expose portions of the etch stop layer 108. The patterning stack may then be removed as shown in FIG. 1H.

At block 710, the etch stop layer may be removed to expose the metal surface. This removal process may correspond to the step described with reference to FIG. 1I, where the exposed portions of the etch stop layer 108 may be selectively removed using various etching techniques to expose the underlying metal surface of the first metal region 106. Following this step, a metal layer may be deposited as shown in FIG. 1J to establish electrical connections between different levels of the interconnect structure.

FIG. 8 illustrates a flow diagram of a method for selective etch stop layer deposition with air gap formation, in accordance with an embodiment.

At block 802, a substrate with a first metal region comprising a metal surface and a first dielectric region comprising a dielectric surface may be provided. This substrate may be similar to the substrate 100 described with reference to FIG. 1A.

At block 804, an etch stop layer may be selectively deposited over the metal surface. This selective deposition process may follow the methods described with reference to FIG. 2C, where the etch stop layer 108 may be selectively deposited on the metal surface while leaving the dielectric surface substantially free of the etch stop layer. In some embodiments, the selective deposition may utilize the cyclic deposition process illustrated in FIG. 4.

At block 806, the first dielectric region may be removed to expose sidewalls of the first metal region. This etching process may correspond to the steps described with reference to FIGS. 2B and 3A, where the dielectric material may be etched away using various techniques to expose the sidewalls of the metal region. The etch stop layer may protect the top surface of the metal region during this process.

At block 808, a barrier layer may be formed over the sidewalls of the first metal region. This barrier formation may follow the process described with reference to FIG. 2C, where a barrier layer 210 may be deposited over the exposed sidewalls of the metal region. The barrier layer may comprise various materials including transition metal dichalcogenides (TMDCs), graphene, nitrides, or oxides, as previously detailed.

At block 810, a dielectric layer may be deposited to fill openings between the sidewalls, with the dielectric layer comprising an air gap. This step may correspond to the processes described with reference to FIG. 2D, where the dielectric layer 204 comprising the air gap 202 may be formed. The air gap may be created using methods such as the ashless carbon approach or nonconformal CVD deposition as previously detailed, resulting in a void region with a dielectric constant between 1.0 and 1.1. In some embodiments, the dielectric layer deposition may follow the process described with reference to FIGS. 3B and 3C. After the dielectric layer deposition, the etch stop layer may be removed as described previously.

At block 812, a second metal region may be formed over the first metal region and a second dielectric region over the dielectric layer. This step may correspond to the structures shown in FIGS. 2E, 2F, and 3D, where additional metallization levels may be built up. The second dielectric region may also incorporate air gaps as illustrated in FIG. 2F, further extending the parasitic capacitance reduction benefits throughout the interconnect hierarchy. In some embodiments, after the block 812, the substrate may be processed following the steps illustrated in FIGS. 3E-3G.

In various embodiments, the methods illustrated in FIGS. 1A through 8 may be implemented using a cluster tool semiconductor processing system that enables in-situ fabrication of the various structures. In one or more embodiments, the processing system may comprise a central transfer chamber connected to multiple process chambers through vacuum-sealed load-lock mechanisms. The transfer chamber may house a robotic arm for wafer handling that can transport substrates between the various process chambers without breaking vacuum, thereby minimizing contamination and oxidation between processing steps.

In various embodiments, the processing system may include dedicated chambers for selective etch stop layer deposition as shown in FIGS. 1C, 2A, and 3E, dielectric deposition as illustrated in FIGS. 1D, 2D, and 3B, etching processes depicted in FIGS. 1F, 1I, 2B, and 3F, metal deposition as shown in FIGS. 1J, 2E, and 3D, and surface treatment processes illustrated in FIG. 1B. Each chamber may be equipped with appropriate gas delivery systems, temperature control mechanisms, and plasma generation capabilities as required by the specific processes. For the selective etch stop layer deposition using the cyclic process illustrated in FIG. 4, specialized chambers may be configured with precise precursor delivery systems for the metal-containing precursors and reactive precursors, along with temperature control systems capable of maintaining the low temperatures (below 100° C.) required for selective growth as validated by the XPS data in FIGS. 5A-5G and FIG. 6.

In one or more embodiments, the processing system may further comprise a controller coupled to the various chambers and subsystems. The controller may include one or more processors, memory devices, and input/output interfaces configured to execute program instructions that implement the process flows depicted in FIGS. 7 and 8. The controller may be programmed to coordinate the sequential operations across multiple chambers, including controlling process parameters such as gas flow rates, chamber pressures, substrate temperatures, plasma power levels, and process timing to achieve the desired selective deposition, etching, and film formation steps. The controller may also receive feedback from in-situ sensors and metrology tools to enable real-time process adjustments and ensure consistent results across multiple wafers. In some embodiments, the controller may implement recipe management, allowing for flexible configuration of process sequences to accommodate different etch stop layer materials and integration schemes as described in the previous embodiments.

In some embodiments, additional chambers may be dedicated to metrology and inspection functions to enable in-line process monitoring and control. For example, XPS analysis chambers similar to those used to generate the data in FIGS. 5A-5G and FIG. 6 may be incorporated to verify selective deposition quality. This integrated processing approach may enhance process reliability and device performance by preventing interfacial contamination that may otherwise occur during atmospheric transfers between separate tools, which is particularly important for maintaining the selectivity of the etch stop layer deposition and the integrity of air gap structures formed according to the methods described in previous embodiments.

While the disclosed aspects are described primarily in the context of selective etch stop layer deposition for advanced interconnect structures in semiconductor devices, it should also be appreciated that these aspects may apply to various other semiconductor fabrication processes requiring selective material deposition and parasitic capacitance reduction. In particular, aspects of this disclosure may similarly apply to through-silicon via (TSV) structures in 3D integrated circuits, interposers for heterogeneous integration, radio frequency (RF) devices where signal isolation is critical, memory cell fabrication where capacitance affects retention time, high-speed logic circuits requiring minimal RC delay, power management integrated circuits (PMICs) where parasitic effects impact efficiency, mixed-signal applications requiring isolation between analog and digital components, and silicon photonics where precise control of material interfaces affects optical performance. The selective deposition techniques and air gap formation methods described herein may be adapted to these various applications to achieve similar benefits in terms of reduced parasitic effects and improved device performance.

Example embodiments of the invention are described below. Other embodiments can also be understood from the entirety of the specification as well as the claims filed herein.
Example 1. A method for processing a substrate, the method including: providing a substrate including a metal surface and a dielectric surface; selectively depositing an etch stop layer over the metal surface, where the selectively depositing includes cyclically exposing the substrate to a pulse of a metal-containing precursor and a pulse of a reactive precursor; depositing a dielectric layer over the etch stop layer and the dielectric surface; etching the dielectric layer to expose a top surface of the etch stop layer; and removing the etch stop layer to expose the metal surface.
Example 2. The method of example 1, further including depositing a metal layer over the metal surface after the removing.
Example 3. The method of one of examples 1 or 2, where the metal-containing precursor includes dimethylaluminum isopropoxide and the reactive precursor includes an organic compound including carboxylic acid or alcohol.
Example 4. The method of one of examples 1 to 3, where the etch stop layer includes silicon carbonitride (SiCN), silicon nitride (SiN), silicon oxycarbonitride (SiOCN), aluminum oxynitride (AlON), aluminum oxycarbide (AlOC), aluminum nitride (AlN), or aluminum carbonitride (AlCN).
Example 5. The method of one of examples 1 to 4, where the etch stop layer includes a thickness smaller than 5 nm.
Example 6. The method of one of examples 1 to 5, further including treating the dielectric surface with a surface treatment material before the selectively depositing.
Example 7. The method of one of examples 1 to 6, where the surface treatment material includes amines, carbenes, or silanes including trimethylsilyldimethylamine (TMSDMA).
Example 8. A method for processing a substrate, the method including: providing a substrate including a first metal region including a metal surface and a first dielectric region including a dielectric surface; selectively depositing an etch stop layer over the metal surface; etching the first dielectric region, the etching exposing sidewalls of the first metal region; and depositing a dielectric layer to fill openings between the sidewalls, the dielectric layer including an air gap.
Example 9. The method of example 8, where the selectively depositing includes cyclically exposing the substrate to a pulse of a metal-containing precursor and a pulse of a carboxylic acid or alcohol.
Example 10. The method of one of examples 8 or 9, further including forming a barrier layer over the sidewalls of the first metal region before the depositing.
Example 11. The method of one of examples 8 to 10, where the barrier layer includes transition metal dichalcogenides (TMDC), graphene, nitrides, or oxides.
Example 12. The method of one of examples 8 to 11, further including treating the dielectric surface with a surface treatment material before the selectively depositing, where the surface treatment material includes trimethylsilyldimethylamine (TMSDMA).
Example 13. The method of one of examples 8 to 12, where the air gap includes a dielectric constant between 1.0 and 1.1.
Example 14. The method of one of examples 8 to 13, where the air gap is formed by: depositing an ashless carbon material within the openings; depositing a dielectric material over the ashless carbon material; and annealing the substrate to decompose and remove the ashless carbon material through the dielectric material, where the removal of the ashless carbon material creates the air gap within the dielectric layer.
Example 15. The method of one of examples 8 to 14, further including forming a second metal region over the first metal region and a second dielectric region over the dielectric layer.
Example 16. The method of one of examples 8 to 15, where the second dielectric region includes an air gap, the air gap including a dielectric constant between 1.0 and 1.1.
Example 17. A method for processing a substrate, the method including: providing a substrate, the substrate including a first etch stop layer deposited over a first metal region; depositing a dielectric layer over the first etch stop layer and openings in the first metal region; etching the dielectric layer to expose a top surface of the first etch stop layer; removing the first etch stop layer and forming a second metal region over the first metal region; selectively depositing a second etch stop layer over the second metal region; removing the dielectric layer to expose sidewalls of the first and second metal regions; and forming a dielectric region in openings between the sidewalls.
Example 18. The method of example 17, where the dielectric region includes an air gap, the air gap including a dielectric constant between 1.0 and 1.1.
Example 19. The method of one of examples 17 or 18, where the air gap is formed by: depositing an ashless carbon material within the openings; depositing a dielectric material over the ashless carbon material; and annealing the substrate to decompose and remove the ashless carbon material through the dielectric material, where the removal of the ashless carbon material creates the air gap within the dielectric region.
Example 20. The method of one of examples 17 to 19, further including disposing a barrier layer over the sidewalls of the first and second metal regions before the forming, the barrier layer including transition metal dichalcogenides (TMDC), graphene, nitrides, or oxides.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-8 may be combined in further embodiments. It is therefore intended that the appended claims encompass any such modifications or embodiments.

What is claimed is:

1. A method for processing a substrate, the method comprising:
providing a substrate comprising a metal surface and a dielectric surface;
selectively depositing an etch stop layer over the metal surface, wherein the selectively depositing comprises cyclically exposing the substrate to a pulse of a metal-containing precursor and a pulse of a reactive precursor;
depositing a dielectric layer over the etch stop layer and the dielectric surface;
etching the dielectric layer to expose a top surface of the etch stop layer; and
removing the etch stop layer to expose the metal surface.

2. The method of claim 1, further comprising depositing a metal layer over the metal surface after the removing.

3. The method of claim 1, wherein the metal-containing precursor comprises dimethylaluminum isopropoxide and the reactive precursor comprises an organic compound comprising carboxylic acid or alcohol.

4. The method of claim 1, wherein the etch stop layer comprises silicon carbonitride (SiCN), silicon nitride (SiN), silicon oxycarbonitride (SiOCN), aluminum oxynitride (AlON), aluminum oxycarbide (AlOC), aluminum nitride (AlN), or aluminum carbonitride (AlCN).

5. The method of claim 1, wherein the etch stop layer comprises a thickness smaller than 5 nm.

6. The method of claim 1, further comprising treating the dielectric surface with a surface treatment material before the selectively depositing.

7. The method of claim 6, wherein the surface treatment material comprises amines, carbenes, or silanes comprising trimethylsilyldimethylamine (TMSDMA).

8. A method for processing a substrate, the method comprising:
providing a substrate comprising a first metal region comprising a metal surface and a first dielectric region comprising a dielectric surface;
selectively depositing an etch stop layer over the metal surface;
etching the first dielectric region, the etching exposing sidewalls of the first metal region; and
depositing a dielectric layer to fill openings between the sidewalls, the dielectric layer comprising an air gap.

9. The method of claim 8, wherein the selectively depositing comprises cyclically exposing the substrate to a pulse of a metal-containing precursor and a pulse of a carboxylic acid or alcohol.

10. The method of claim 8, further comprising forming a barrier layer over the sidewalls of the first metal region before the depositing.

11. The method of claim 10, wherein the barrier layer comprises transition metal dichalcogenides (TMDC), graphene, nitrides, or oxides.

12. The method of claim 8, further comprising treating the dielectric surface with a surface treatment material before the selectively depositing, wherein the surface treatment material comprises trimethylsilyldimethylamine (TMSDMA).

13. The method of claim 8, wherein the air gap comprises a dielectric constant between 1.0 and 1.1.

14. The method of claim 13, wherein the air gap is formed by:
depositing an ashless carbon material within the openings;
depositing a dielectric material over the ashless carbon material; and
annealing the substrate to decompose and remove the ashless carbon material through the dielectric material, wherein the removal of the ashless carbon material creates the air gap within the dielectric layer.

15. The method of claim 8, further comprising forming a second metal region over the first metal region and a second dielectric region over the dielectric layer.

16. The method of claim 15, wherein the second dielectric region comprises an air gap, the air gap comprising a dielectric constant between 1.0 and 1.1.

17. A method for processing a substrate, the method comprising:
providing a substrate, the substrate comprising a first etch stop layer deposited over a first metal region;
depositing a dielectric layer over the first etch stop layer and openings in the first metal region;
etching the dielectric layer to expose a top surface of the first etch stop layer;
removing the first etch stop layer and forming a second metal region over the first metal region;
selectively depositing a second etch stop layer over the second metal region;
removing the dielectric layer to expose sidewalls of the first and second metal regions; and
forming a dielectric region in openings between the sidewalls.

18. The method of claim 17, wherein the dielectric region comprises an air gap, the air gap comprising a dielectric constant between 1.0 and 1.1.

19. The method of claim 18, wherein the air gap is formed by:
depositing an ashless carbon material within the openings;
depositing a dielectric material over the ashless carbon material; and
annealing the substrate to decompose and remove the ashless carbon material through the dielectric material, wherein the removal of the ashless carbon material creates the air gap within the dielectric region.

20. The method of claim 17, further comprising disposing a barrier layer over the sidewalls of the first and second metal regions before the forming, the barrier layer comprising transition metal dichalcogenides (TMDC), graphene, nitrides, or oxides.
